(19) United States
(12) Patent Application Publication
(10) Pub. No.: US 2025/0210906 A1
(43) Pub. Date: Jun. 26, 2025

(54) Automation Component

(71) Applicant: Siemens Aktiengesellschaft, Muenchen (DE)

(72) Inventors: Stefan GÖRLICH, Illschwang (DE); Stefan HUBMANN, Sulzbach-Rosenberg (DE)

(21) Appl. No.: 18/989,269

(22) Filed: Dec. 20, 2024

(30) Foreign Application Priority Data
Dec. 21, 2023 (EP) 23219354

(51) Int. Cl. H01R 13/52; H01R 25/00; H01R 27/02

(52) U.S. Cl. CPC H01R 13/5202; H01R 25/006; H01R 27/02

(57) ABSTRACT

An automation component for industrial automation, wherein feet include fastening areas for fastening to a mounting surface, where a contact surface is arranged within a fastening area, a hole in a fastening opening is arranged within the contact surface that is structured to protrude from the fastening area, thereby forming a recess annularly enclosing the contact surface, the recess is arranged between the protruding contact surface and an outer edge area formed as a collar arranged lower than the protruding contact surface and has a collar surface directed toward the mounting surface, an annular sealer with a sealing lip, a first bearing surface and a second bearing surface, is structured such that the sealing lip is arranged in the recess, the first bearing surface is arranged on the collar surface and the second bearing surface is arranged toward the surface, and the sealing element annularly encloses the contact surface.

### BACKGROUND OF THE INVENTION

### 1. Field of the Invention

The invention relates to an automation component for industrial automation having a housing comprising an upper part and a lower part, where the upper part and the lower part are structured such that, in order to fasten the automation component to a mounting surface, the housing has a first fastening opening and a second fastening opening.

### 2. Description of the Related Art

When automation devices are used in medical settings or in the food and beverage industry, for example, they must meet specific requirements relating to hygiene. These requirements substantially relate to the ease of cleaning of the devices used.

The following automation devices or components are known from the prior art:

Balluff Network Interface IO-Link BNI IOL-252-000-Z013 according to the installation instructions.

Digital Module AXL E IOL DI16 M12 6P.

SIMATIC ET 200AL, DI 8x 24 V DC, 8XM8, Degree of protection IP67 according to the data sheet dated May 21, 2020 or according to the device manual A5E32349561-AD dated August 2021.

All these conventional automation components have the drawback that they are designed to be screwed flat onto a mounting surface with their fastening opening, thus creating a circumferential dirt-collecting edge.

### SUMMARY OF THE INVENTION

It is an object of the invention to provide an automation component that meets the requirements of the food industry with respect to hygiene.

This and other objects and advantages are achieved in accordance with the invention by an automation component in which the lower part has a first foot and a second foot, where the feet are formed in one piece with the lower part and the first fastening opening extends through the first foot and the second fastening opening extends through the second foot. In accordance with the invention, the feet have a fastening area for fastening to the mounting surface, for this purpose, a contact surface is arranged within the fastening area, where a hole in the fastening opening is in turn arranged within the contact surface, where the contact surface is structured such that it protrudes from the fastening area, thereby forming a recess enclosing the contact surface in an annular manner. The recess is thus arranged between the protruding contact surface and an outer edge area of the fastening area, where the outer edge area is formed as a circumferential collar around the recess, where the collar is arranged lower than the protruding contact surface and has a collar surface directed toward the surface. In addition, an annular sealing element having a sealing lip, a first bearing surface and a second bearing surface, is structured such that the sealing lip is arranged in the recess, the first bearing surface is arranged on the collar surface and the second bearing surface is arranged toward the mounting surface, where the sealing element encloses the protruding contact surface in an annular manner.

These structures prevent the adhesion of impurities and the resulting contamination of the automation component. In a particular embodiment, the sealing element lies flush with the outer surface of the foot and the thickness of the sealing element at this point is slightly greater than the protruding contact surface, so that, when installed, the sealing element is arranged compressed between the collar surface and the mounting surface such that a gap-free transition is formed therebetween. The thickness is slightly greater than the distance between the two surfaces that corresponds to the extent to which the contact surface protrudes beyond the collar.

The invention offers the possibility of cost-effective hygienic sealing of fastening areas or screw-on areas. In the food and beverage sector, the additional upfront costs of implementing this invention are justifiable as they are significantly lower than the ongoing and higher cleaning expenses required for components that are not embodied in a hygienic manner.

The feet provide sufficient accessibility to all surfaces of the automation assembly for cleaning, even with low-pressure water and by hand using a cleaning cloth.

Accordingly, the housing and thus the upper part and the lower part are formed as a longitudinally extending enclosure between the first foot and the second foot, where the feet have at least a length such that the surface of the lower part is spaced apart from the surface such that a human hand with a cleaning agent can slide through.

In order to ensure that liquids can drain off the automation component easily and quickly, the housing and thus the upper part and the lower part are structured such that, in a preferred installation position in which the fastening openings lie perpendicularly one above the other, the housing tapers in the direction of the second fastening opening starting from the first fastening opening.

It is more advantageous if the housing is structured such that surfaces are shaped such that accumulation of impurities is avoided or minimized. This is achieved by eliminating sharp edges or indentations.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The drawing shows an exemplary embodiment of the invention, in which:

FIG. 1 shows an automation component as a decentralized I/O device in accordance with the invention;

FIG. 2 shows a three-dimensional view of a rear side of the automation component of FIG. 1;

FIG. 3 shows a view of a front side of the automation component of FIG. 1;

FIG. 4 shows a view of an underside of the automation component of FIG. 1;

FIG. 5 shows a detailed view of a foot of the automation component of FIG. 1;

FIG. 6 shows a sealing element in accordance with the invention;

FIG. 7 shows another detailed view of a foot of the automation component in accordance with the invention; and

FIG. 8 shows a further detailed view of a foot of the automation component in accordance with the invention.

### DETAILED DESCRIPTION OF THE EXEMPLARY EMBODIMENTS

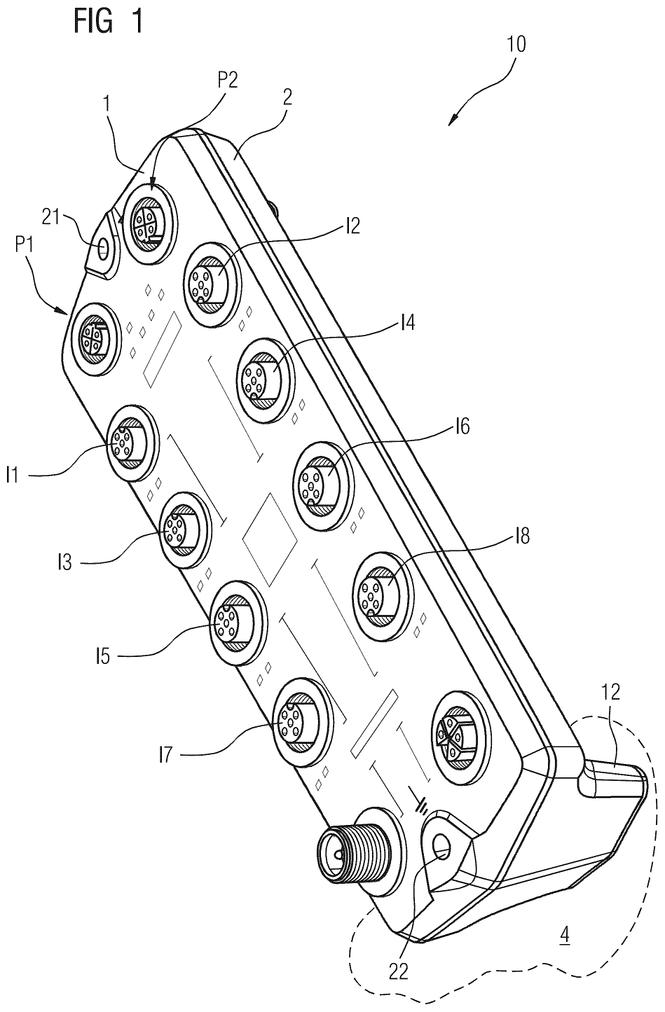

FIG. 1 shows an automation component 10 for industrial automation. The automation component 10 is formed as an I/O assembly for industrial automation. The automation component 10 has a housing 3 comprising an upper part 1 and a lower part 2, where the upper part 1 and the lower part 2 are structured such that, to fasten the automation component 10 to a mounting surface 4, the housing 3 has a first fastening opening 21 and a second fastening opening 22.

For communication with sensors or actuators, for example, using the I/O link protocol, the automation component 10 has one to eight I/O connectors 11, . . . , 18. To enable the automation component 10 to receive signals from a higher-level controller, the automation component 10 has a first PROFINET connector P1. A further second PROFINET connector P2 is used to connect other automation components to PROFINET.

The lower part 2 has a first foot 11 and a second foot 12, where the feet 11,12 are formed in one piece with the lower part 2.

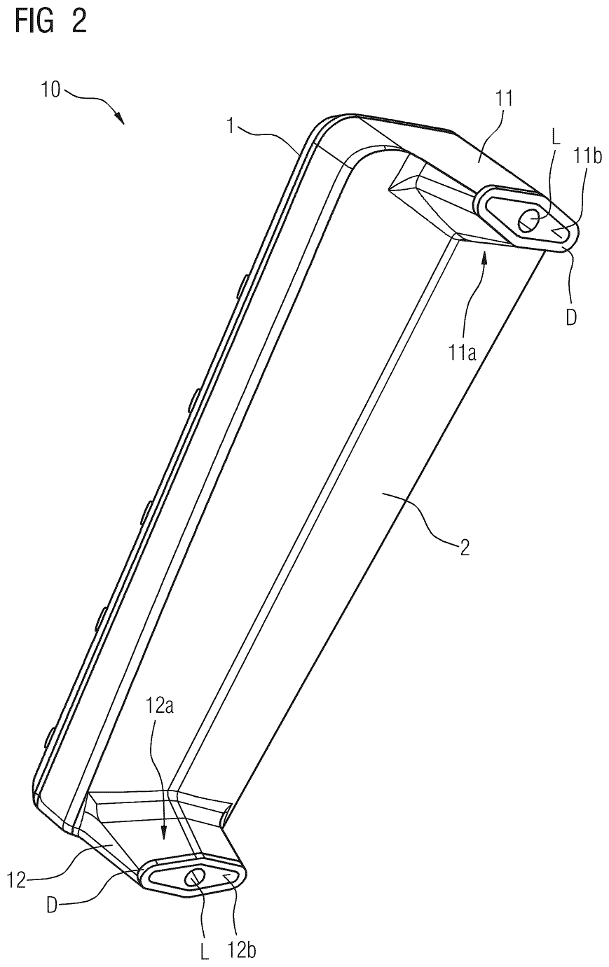

FIG. 2 illustrates the one-piece embodiment of the first foot 11 and the second foot 12. The first fastening opening 21 extends through the first foot 11 and the second fastening opening 22 extends through the second foot 12. For fastening to the mounting surface 4, the first foot 11 and the second foot 12 have a fastening area 11a or 12a. For fastening to the mounting surface 4, a contact surface 11b or 12b is arranged within the fastening area 11a, 12a. A hole L in the first fastening opening 21 is in turn arranged within the first contact surface 11b. A hole L in the second fastening opening 22 is in turn arranged in the second contact surface 12b.

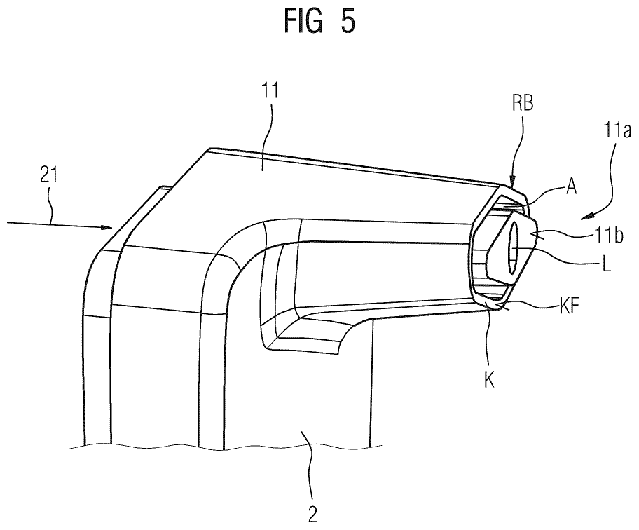

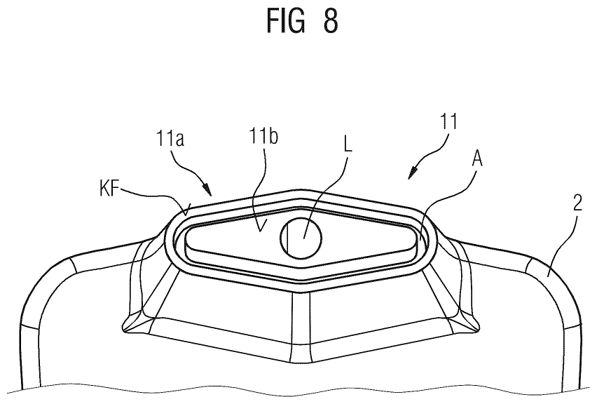

The contact surfaces 11b, 12b are structured such that they protrude from the respective fastening area 11a, 12a, thereby forming a recess A enclosing the contact surface 11b, 12b in an annular manner (this is in particular illustrated in FIG. 5 and FIG. 8).

A sealing element D is in each case inserted in the first foot 11 and the second foot 12. The sealing element D lies flush with the outer surface of the first foot 11, where the thickness of the sealing element is slightly greater than the protruding contact surface, so that, when installed, the sealing element D is arranged compressed between a collar surface KF and the mounting surface 4 so that a gap-free transition is formed therebetween.

FIG. 5 shows a detail of the first foot 11 in a sectional view. For fastening to the mounting surface 4, the first foot 11 has a fastening area 11a, for this purpose, a contact surface 11b is arranged within the fastening area 11a, where a hole L of the fastening opening 21 is in turn arranged within the contact surface 11b.

The contact surface 11b is structured such that it protrudes from the fastening area 11a, thereby forming a recess A enclosing the contact surface 11b in an annular manner. The recess A is thus arranged between the protruding contact surface 11b and an outer edge area RB of the fastening area 11a. The outer edge area RB is formed as a circumferential collar K around the recess A, where the collar K is arranged lower than the protruding contact surface 11b and has a collar surface KF directed toward the surface 4.

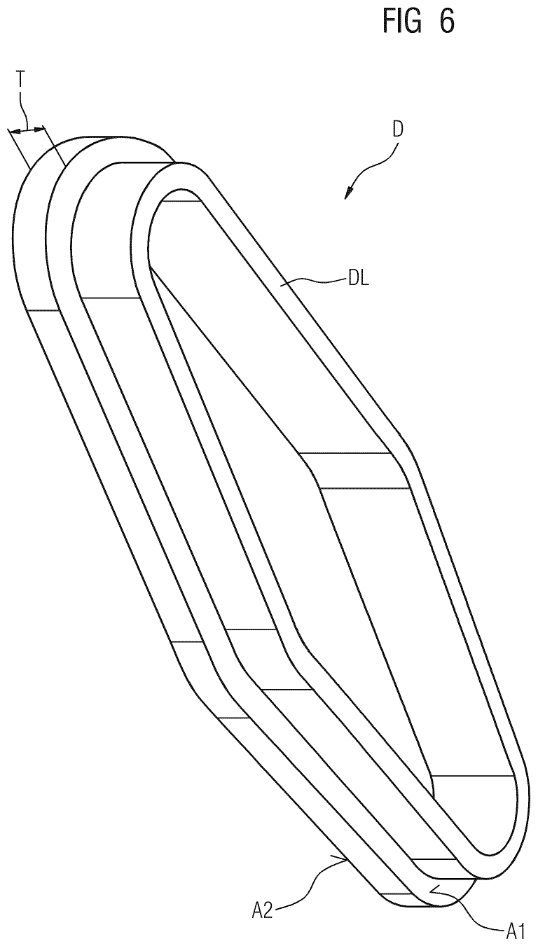

FIG. 6 shows the annular sealing element D. The sealing element D has a sealing lip DL, a first bearing surface A1 and a second bearing surface A2. The sealing element D is structured such that the sealing lip DL is arranged as a type of mounting lip in the recess A, the first bearing surface A1 is arranged on the collar surface KF and the second bearing surface A2 is arranged toward the surface 4, herein the sealing element D encloses the protruding contact surface 11b in an annular manner.

The sealing element D has a thickness T, where the thickness T is selected to be slightly greater than the distance between the collar surface KF and the mounting surface 4, so that when installed, the sealing element D is arranged compressed between the collar surface KF and the mounting surface 4 such that a gap-free transition is formed therebetween.

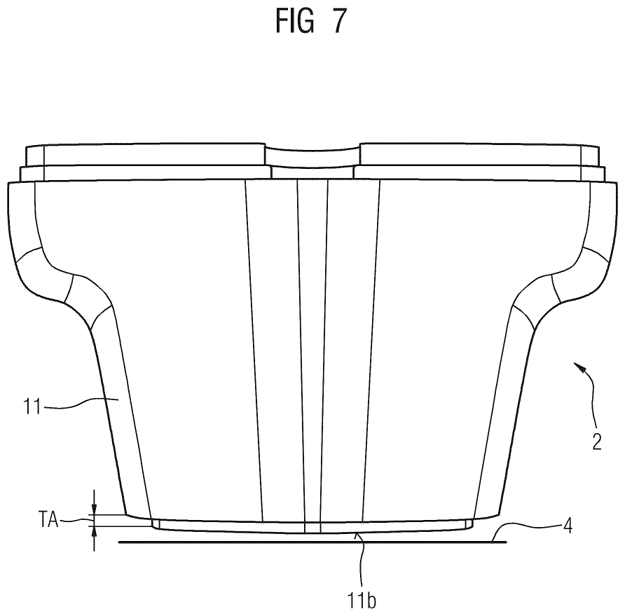

FIG. 7 once again illustrates the relationship between the thickness T of the sealing element D and the distance TA to the surface 4.

FIG. 8 once again shows another perspective view of the first foot 11.

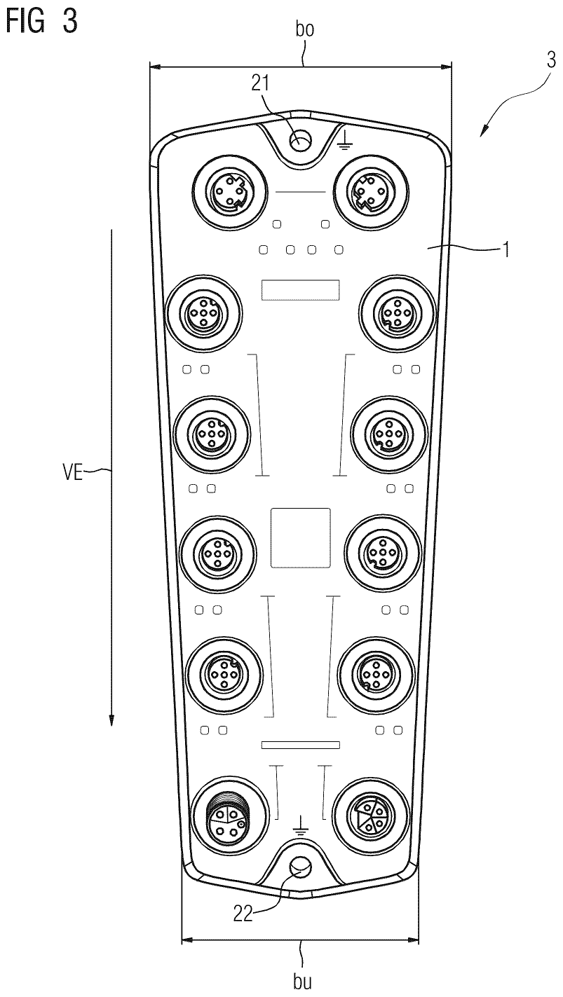

In FIG. 3 the housing 3 and thus the upper part 1 and the lower part 2 are structured such that, in a preferred installation position VE, the first fastening opening 21 is located at the top and the second fastening opening 22 is located at the bottom. The fastening openings 21,22 lie perpendicularly one above the other. The housing 3 is structured to taper in the direction of the second fastening opening 22 starting from the fastening opening 21. A width at the top bo is selected to be greater than a width at the bottom bu. Accordingly, the automation component 10 is wider at the first fastening opening 21 than it is at the second fastening opening 22. As a result, liquids can drain off the automation component easily and quickly.

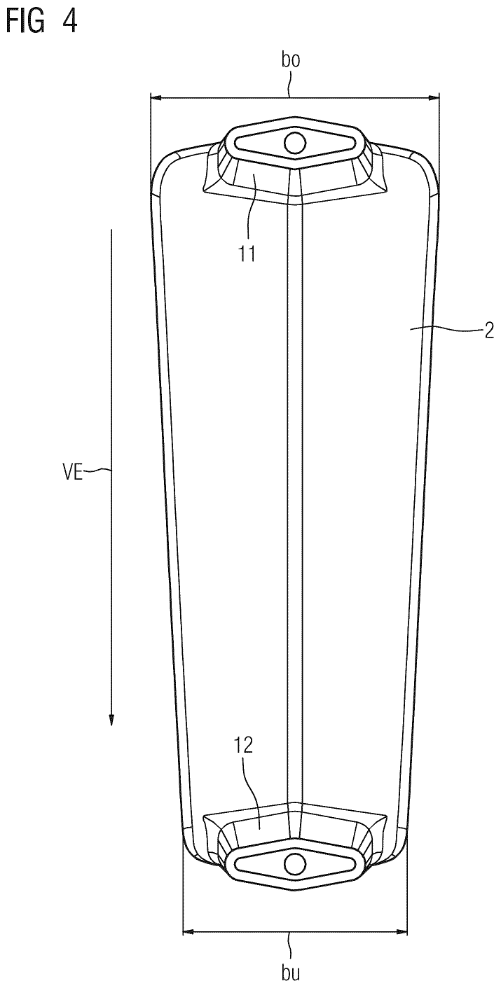

As FIG. 4 and in particular FIG. 2 show, the embodiment of the feet 11,12 enables sufficiently good accessibility to all surfaces of the automation assembly 10 for cleaning, even with low pressure water and by hand using a cleaning cloth. This means that the longitudinally extending enclosure between the first foot 11 and the second foot 12 is structured such that the surface of the lower part 2 is spaced apart from the surface 4 such that a human hand with a cleaning agent can slide through.

Throughout, the housing 3 is structured such that all surfaces and transitions and curves are shaped such that the accumulation of impurities is avoided or minimized.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements that perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. An automation component for industrial automation, the automation component comprising:
a housing including an upper part and a lower part, the upper and lower parts being configured such that the housing has a first fastening opening and a second fastening opening to fasten the automation component to a mounting surface;
wherein the lower part includes a first foot and a second foot;
wherein the first foot and second are formed in one piece with the lower part and the first fastening opening extends through the first foot and the second fastening opening extends through the second foot, the first and second feet having a fastening area for fastening to the mounting surface, and for this purpose, a contact surface being arranged within the fastening area;
wherein a hole of the fastening opening is in turn arranged within the contact surface, the contact surface being structure to protrude from the fastening area and form a recess enclosing the contact surface in an annular manner, the recess being arranged between the protruding contact surface and an outer edge area of the fastening area, the outer edge area being formed as a circumferential collar around the recess;
wherein the circumferential collar is arranged lower than the protruding contact surface and has a collar surface oriented toward the mounting surface, and an annular sealing element having a sealing lip, a first bearing surface and a second bearing surface, is formed such that the sealing lip is arranged in the recess, the first bearing surface is arranged on the collar surface and the second bearing surface is arranged toward the surface; and
wherein the annular sealing element encloses the protruding contact surface in an annular manner.

2. The automation component as claimed in claim 1, wherein the housing including the upper part and the lower part are formed as a longitudinally extending enclosure between the first foot and the second foot; and wherein the first and second feet have at least a length such that the surface of the lower part is spaced apart from the mounting surface such that a human hand with a cleaning agent can slide through.

3. The automation component as claimed in claim 1, wherein the housing including the upper part and the lower part are structured such that, in a preferred installation position in which the fastening openings lie perpendicularly one above the other, the housing tapers in a direction of the second fastening opening starting from the first fastening opening.

4. The automation component as claimed in claim 2, wherein the housing including the upper part and the lower part are structured such that, in a preferred installation position in which the fastening openings lie perpendicularly one above the other, the housing tapers in a direction of the second fastening opening starting from the first fastening opening.

5. The automation component as claimed in claim 1, wherein the housing is structured such that surfaces are shaped such that accumulation of impurities is avoided or minimized.

6. The automation component as claimed in claim 2, wherein the housing is structured such that surfaces are shaped such that accumulation of impurities is avoided or minimized.

7. The automation component as claimed in claim 3, wherein the housing is structured such that surfaces are shaped such that accumulation of impurities is avoided or minimized.
